(19) United States
(12) Patent Application Publication
(10) Pub. No.: US 2011/0193215 A1
(43) Pub. Date: Aug. 11, 2011

(54) SEMICONDUCTOR PACKAGE

(75) Inventors: Masahiro TOYAMA, Kodaira (JP); Yutaka UEMATSU, Kawasaki (JP); Hideki OSAKA, Naka-gun (JP)

(73) Assignee: RENESAS ELECTRONICS CORPORATION

(21) Appl. No.: 13/023,565

(22) Filed: Feb. 9, 2011

(30) Foreign Application Priority Data
Feb. 9, 2010 (JP) JP2010-026424

(51) Int. Cl. H01L 23/50

(52) U.S. Cl. 257/691; 257/E23.079

(57) ABSTRACT

Means for decreasing parasitic inductance by a realistic mounting method is provided. On a surface layer of a semiconductor package, there is provided a ground pad having a plurality of comb-tooth-shaped ground pads which are connecting points for wire bonding and are protruded on the surface layer of the semiconductor package. A power-supply pad is arranged between the comb-tooth-shaped ground pads. Two long and short ground wires are arranged in one comb-tooth-shaped ground pad. Also, two long and short power-supply wires are arranged in one power-supply pad. By arranging the long ground wire and the long power-supply wire so as to be parallel and close to each other and arranging the short power-supply wire and the short ground wire so as to be parallel and close to each other, the parasitic inductance is decreased.

### CROSS-REFERENCE TO RELATED APPLICATION

The present application claims priority from Japanese Patent Application No. 2010-26424 filed on Feb. 9, 2010, the content of which is hereby incorporated by reference into this application.

### TECHNICAL FIELD OF THE INVENTION

The present invention relates to a semiconductor package. More particularly, the present invention relates to a pad arrangement and a pad shape of a semiconductor package for enabling to decrease parasitic inductance without being affected by errors caused upon bonding.

### BACKGROUND OF THE INVENTION

A semiconductor package has a role to electrically connect a semiconductor chip and a printed board, and has a structure of connection of a signal pin of the semiconductor chip and signal wiring of the printed board. At the same time, the semiconductor package has a role to supply power to the semiconductor chip and electrically connects a power-supply pin and a ground pin of the chip and connects power supply and ground of the printed board.

In order to achieve stable operation of the semiconductor chip, dynamic voltage variation, that is power supply noise of power supply and ground at a power feed point of the semiconductor chip have to be suppressed. On the other hand, due to high speed of an operating frequency and low voltage operation for the semiconductor chip in recent years, there are tendencies that the power supply noise is increased and a noise margin is decreased. Therefore, the power feed performance of the semiconductor package has to be improved.

When time change of current flowing through the chip is expressed by “di/dt” and a variable voltage is expressed by “Vnoise”, the dynamic power supply noise can be expressed by “Vnoise=L×di/dt”. Here, “L” is an inductance of a power feed path, and improvement in the power supply noise can be expected by decreasing the inductance of the power feed path of the semiconductor package.

Also, in order to handle high speed of signal transmission of the semiconductor chip, decrease in simultaneous drive noise caused by the inductance among the signal wiring of the chip, I/O power supply, and ground has been a problem, and the inductance between the I/O power supply and the ground has to be also decreased.

As the semiconductor package, there is the one using wire bonding for the connection between a semiconductor chip and a package. FIG. 1 is a bird' s eye view of an example of a state in which a package connected by using the wire bonding is mounted on a printed board. Also, FIG. 2 is a cross-sectional view of the example of the state in which the package connected by using the wire bonding is mounted on the printed board.

A semiconductor chip 1 is fixed on a surface layer of a package 2. In order to establish connections among a signal, power supply, and ground, the semiconductor chip 1 is connected to a conductive layer 5 of the package 2 by bonding wires 4. The package 2 has a multilayer structure with two or more layers, and each conductive layer is connected to the other by a via hole 6. Moreover, the package 2 and a printed board 3 are connected to each other by solder balls 7. Also in the printed board 3, a package-board conductive layer 8 is provided over multiple layers and connected to bypass capacitors 9 via package-board via holes 10.

FIG. 3 is a top-surface view of a part of connection between the power supply and ground in the package connected by using the wire bonding.

A power-supply pad 25 and a ground pad 26 are formed on a semiconductor surface layer surrounding the semiconductor chip 1. Power-supply wires 11 are connected to the power-supply pad 25, and ground wires 12 are connected to the ground pad 26.

Although not illustrated in the drawing, a signal pad is arranged at a position away from the semiconductor chip 1 farther than the power-supply pad 25, and signal wires are bonded thereto so as to pass over the power-supply pad 25 and the ground pad 26. Whether the power-supply pad 25 or the ground pad 26 is closer to the semiconductor chip 1 than the other is a design matter. Therefore, as different from FIG. 3, it is conceivable that the power-supply pad 25 is arranged to be closer to the semiconductor chip 1.

The inductance caused by the bonding wires of the semiconductor package using the wire bonding as described above is obtained by subtracting the sum of mutual inductances between a power-supply wire and a ground wire from the sum of self inductances of the power-supply wire and the ground wire forming a closed loop of a current. FIG. 4 is a model illustrating the relation between the self inductance and the mutual inductance.

In this model, the semiconductor chip 1 is considered to be a constant current supply, and the package 2 is considered to be a direct current power supply. The self inductance of the bonding wire (power-supply wire 11) connected to the power-supply pad 25 is defined as “L_pow”, and the self inductance of the bonding wire (ground wire 12) connected to the ground pad 26 is defined as “L_gnd”. Also, when the mutual inductance between the power-supply bonding wire and the ground bonding wire is defined as “M”, the parasitic inductance L is expressed by a following expression.

[Expression 1]

L=L_{—}pow+L_{—}gnd−2×M

As is clear from Expression 1, in order to decrease the parasitic inductance, each self inductance may be decreased and the mutual inductance M may be increased.

In the package as illustrated in FIG. 3, the power-supply wire 11 and the ground wire 12 have a different wire length from the other. Therefore, even when the power-supply wire 11 and the ground wire 12 are arranged to be adjacent to each other, the mutual inductance becomes small. Therefore, the parasitic inductance of the loop formed by the power-supply wire 11 and the ground wire 12 becomes large, and this is a cause of the decrease in the power feed performance of the package. Moreover, a mutual inductance between the ground wire 12 and the signal wire not illustrated in the drawing similarly becomes small, and this is a cause of deterioration of the simultaneous drive noise.

For this problem, a lot of solution means have been proposed in past.

The invention described in Japanese Patent Application Laid-Open Publication No. 2000-260809 (Patent Document 1) discloses a technique of decreasing the self inductance by meshing the power-supply pad 25 and the ground pad 26 on the surface layer of the package 2 in a comb-teeth shape to shorten the lengths of both the power-supply wire 11 and the ground wire 12.

FIG. 5 is a top-surface view of a part of connection between the power supply and the ground in the package described in Patent Document 1. As is clear from this drawing, a comb-teeth-shaped power-supply pad 33 and a comb-teeth-shaped ground pad 34 are protruded from the power-supply pad 25 and the ground pad 26, respectively, so that they are meshed with each other. In this manner, distances from a pad 29 of the semiconductor chip 1 to the power supply and the ground can be equalized to each other.

Also, Japanese Patent Application Laid-Open Publication No. 2006-344740 (Patent Document 2) discloses a method of shortening a distance to a via hole by, in addition to the same structure as that of Patent Document 1, arranging the via hole at the comb-teeth-shaped portion of the pad. That is, the mutual inductance M is decreased by arranging the power supply and the ground to be close to each other.

Japanese Patent Application Laid-Open Publication No. H06-112359 (Patent Document 3) also discloses a technique of decreasing the mutual inductance M by shortening a wire length to arrange the power supply and the ground to be close to each other as well as Patent Document 2.

### SUMMARY OF THE INVENTION

However, the techniques described above in Patent Documents also have various problems.

In the techniques described above in Patent Documents, in order to set the same length for the power-supply wire 11 and the ground wire 12, the wires have to be bonded to the power-supply pad 25 and the ground pad 26 on the surface layer of the package 2 so as to provide the same distance as that between the pads on the chip side.

However, when bonding positions on the surface layer of the package 2 are shifted, short circuit between the power supply and the ground may occur. In order to avoid this problem, a wide pitch between the power-supply pad 25 and the ground pad 26 adjacent to each other has to be ensured. Therefore, it is difficult to achieve a narrow pitch between the wires.

Moreover, the mutual inductance between the signal wiring and the ground wire is increased, and therefore, it is also difficult to decrease the simultaneous drive noise.

A preferred aim of the present invention is to provide means for decreasing a parasitic inductance by a realistic mounting method.

The above and other preferred aims and novel characteristics of the present invention will be apparent from the description of the present specification and the accompanying drawings.

The typical ones of the inventions disclosed in the present application will be briefly described as follows.

In a semiconductor package according to a typical embodiment of the present invention, a semiconductor chip is mounted, the semiconductor package is connected to the semiconductor chip by wire bonding, the semiconductor package has a ground pad, which is a connecting point for the wire bonding, on a surface layer of the semiconductor package, the ground pad has a comb-tooth-shaped ground pad protruding on the surface layer of the semiconductor package, and two or more ground wires are connected to the comb-tooth-shaped ground pad.

In the semiconductor package, the semiconductor package further has a power-supply pad to which two or more power-supply wires are connected, and one ground wire of two or more ground wires and one power-supply wire of two or more power-supply wires are substantially parallel to each other and have substantially the same length to be a pair.

In the semiconductor package, two or more comb-tooth-shaped ground pads are provided, and the power-supply pad is arranged on the surface layer of the semiconductor package so as to be sandwiched by two comb-tooth-shaped ground pads.

In the semiconductor package, a difference between lengths of the two or more ground wires connected to the comb-tooth-shaped ground pad is equal to or larger than a distance between wire pads on the semiconductor chip side.

In the semiconductor package, a part of the comb-tooth-shaped ground pad has a length which is twice a portion parallel to the power-supply pad or larger, a ground wire having a length different from that of the ground wire is connected from the semiconductor chip to a tip side of the comb-tooth-shaped ground pad having the length which is twice or larger, and a signal wire is arranged so as to be parallel to the ground wire connected to the tip side of the comb-tooth-shaped ground pad having the length which is twice or larger. In the semiconductor package, the semiconductor package further has an I/O power-supply pad on the surface layer of the semiconductor package, and an I/O power-supply wire is connected to the I/O power-supply pad so as to be parallel to the signal wire.

In the semiconductor package, the semiconductor package has a power-supply via hole so as to be in contact with an outer peripheral side of the semiconductor package of the power-supply pad, has an I/O power-supply via hole so as to be in contact with the semiconductor chip side of the I/O power-supply pad, and has a ground via hole in the comb-tooth-shaped ground pad in the vicinity of the power-supply via hole or the I/O power-supply via hole.

In the semiconductor package, a long wire and a short wire are alternately arranged to each other as each of the power-supply wire and the ground wire being parallel to the power-supply wire and having the same length as that of the power-supply wire, and a long wire and a short wire are alternately arranged to each other as each of the signal wire and the ground wire being parallel to the signal wire and the I/O power-supply wire and having the same length as those of the signal wire and the I/O power-supply wire.

In a semiconductor package according to a typical embodiment of the present invention, a semiconductor chip is mounted, the semiconductor package is connected to the semiconductor chip by wire bonding, the semiconductor package has a ground pad and a power-supply pad, which are connecting points for the wire bonding, on a surface layer of the semiconductor package, the ground pad has a comb-tooth-shaped ground pad protruding on a surface layer of the semiconductor package, the power-supply pad has a comb-tooth-shaped power-supply pad protruding on the surface layer of the semiconductor package, and the comb-tooth-shaped ground pad and the comb-tooth-shaped power-supply pad are adjacent to each other in a peripheral direction of the semiconductor package.

In the semiconductor package, the ground pad is arranged in an inner peripheral side of the semiconductor package, and the power-supply pad is arranged in an outer peripheral side of the semiconductor package.

In the semiconductor package, two wires having different lengths from each other are arranged in each of the comb-tooth-shaped ground pad and the comb-tooth-shaped power-supply pad, and a long wire and a short wire are alternately arranged to each other as each of the two wires arranged in the comb-tooth-shaped ground pad and the two wires arranged in the comb-tooth-shaped power-supply pad.

In the semiconductor package, each shape of the comb-tooth-shaped ground pad and the comb-tooth-shaped power-supply pad is substantially a parallelogram oblique to a tip of the chip.

In the semiconductor package, total four wires having two types of lengths are arranged in the comb-tooth-shaped ground pad, and a via hole for ground connection is arranged between connecting points for the long wire and the short wire arranged in the comb-tooth-shaped ground pad.

In the semiconductor package, the comb-tooth-shaped ground pad is shaped in a parallelogram oblique to the tip of the chip, and each connecting position for the four wires connected to the same comb-tooth-shaped ground pad is arranged so as to have the same distance from a center line of the comb-tooth-shaped ground pad.

In the semiconductor package, the comb-tooth-shaped ground pad is shaped in a trapezoid oblique to a tip of the chip, and each connecting position for the four wires connected to the same comb-tooth-shaped ground pad is arranged so as to have the same distance from a center line of the comb-tooth-shaped ground pad.

In the semiconductor package, total four wires having two types of lengths are arranged in the comb-tooth-shaped power-supply pad, and a via hole for power-supply connection is arranged between connecting points for the long wire and the short wire arranged in the comb-tooth-shaped power-supply pad.

In the semiconductor package, the comb-tooth-shaped power-supply pad is shaped in a parallelogram oblique to a tip of the chip, and each connecting position for the four wires connected to the same comb-tooth-shaped power-supply pad is arranged so as to have the same distance from a center line of the comb-tooth-shaped power-supply pad.

In the semiconductor package, the comb-tooth-shaped power-supply pad is shaped in a trapezoid oblique to a tip of the chip, and each connecting position for the four wires connected to the same comb-tooth-shaped power-supply pad is arranged so as to have the same distance from a center line of the comb-tooth-shaped power-supply pad.

In these semiconductor packages, the semiconductor package has a wiring connected to a wire pad on the surface layer of the semiconductor chip, and power supply and ground are alternately arranged to each other at a connecting portion with wiring in the semiconductor chip.

The effects obtained by typical aspects of the present invention will be briefly described below.

In the semiconductor package according to the typical embodiment of the present invention, by forming the power-supply wire and the ground wire with using wires having lengths of two or more types, the power-supply wire and the ground wire having the same length can be arranged to be parallel and close to each other, and besides, a width between the power-supply pad and the ground pad can be wider than a pad pitch on the chip side. In this manner, short circuit between the power supply and the ground due to shifting of bonding positions can be avoided. As a result, both of decrease of the parasitic inductance and narrow pitch between wires caused by the wires can be achieved.

Moreover, the ground wire, the I/O power-supply wire, and the signal wire can be arranged to be parallel and close to each other, and therefore, a loop inductance among a signal, I/O power supply, and ground can be decreased, so that the simultaneous drive noise can be suppressed.

### BRIEF DESCRIPTIONS OF THE DRAWINGS

FIG. 1 is a bird's eye view of an example of a state in which a package connected by using wire bonding is mounted on a printed board;

FIG. 2 is a cross-sectional view of the example of the state in which the package connected by using wire bonding is mounted on the printed board;

FIG. 3 is a top-surface view of a part of connection between power supply and ground in a package connected by using conventional wire bonding;

FIG. 4 is a model illustrating a relation between self inductance and mutual inductance;

FIG. 5 is a top-surface view of a part of connection between power supply and ground in a package described in Patent Document 1;

FIG. 6 is a top-surface view of a part of connection between power supply and ground in a package according to a first embodiment of the present invention;

FIG. 7 is a top-surface view of a part of connection between power supply and ground in another package according to the first embodiment of the present invention;

FIG. 8 is a top-surface view of a part of connection between power supply and ground in a package according to a second embodiment of the present invention;

FIG. 9 is a top-surface view of a part of connection between power supply and ground in a package according to a third embodiment of the present invention;

FIG. 10 is a top-surface view of a part of connection between power supply and ground in a chip according to the third embodiment of the present invention; and

FIG. 11 is a top-surface view of a part of connection between power supply and ground in another package according to the third embodiment of the present invention.

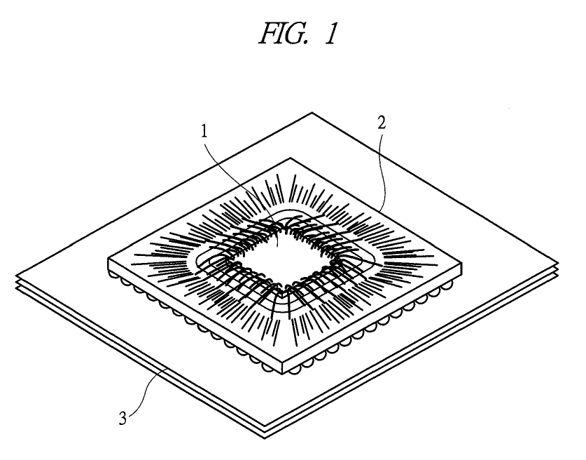

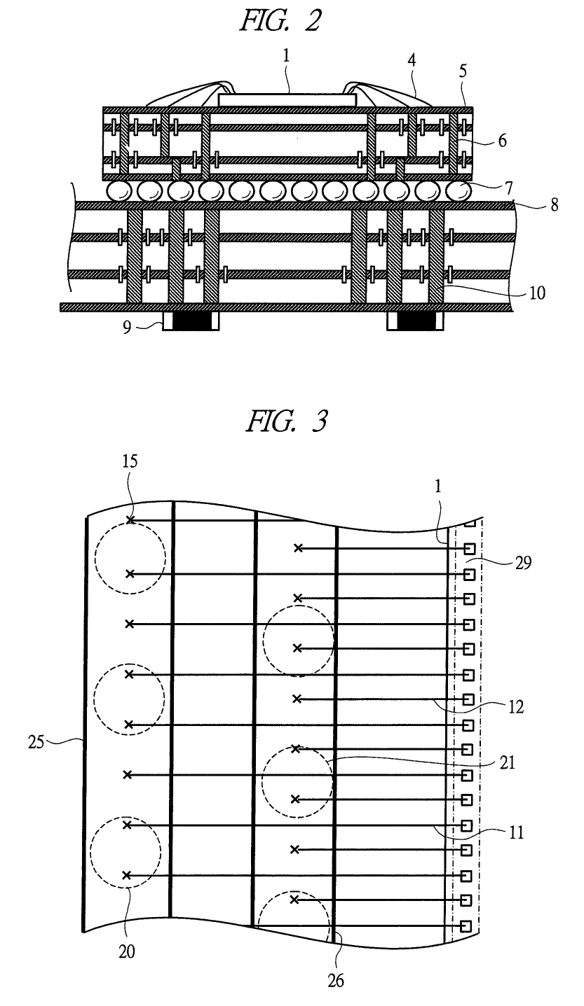

### DESCRIPTIONS OF THE PREFERRED EMBODIMENTS

Hereinafter, embodiments of the present invention will be explained with reference to drawings.

### First Embodiment

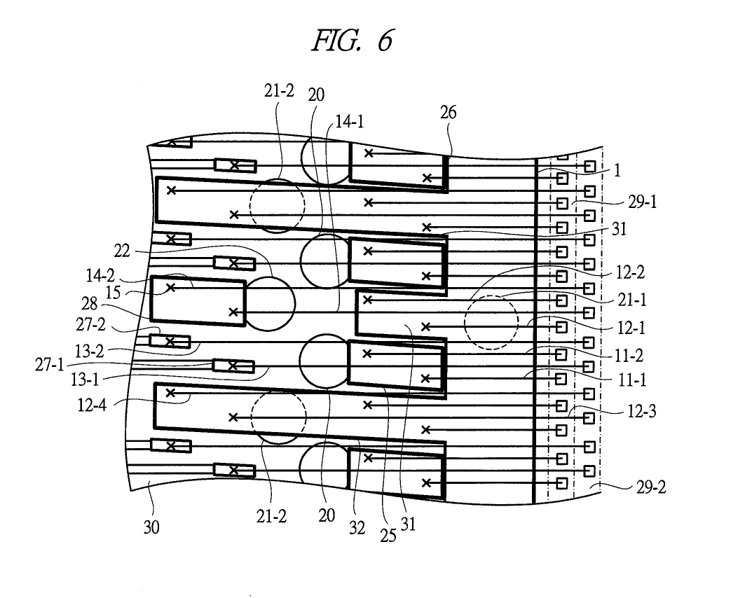

FIG. 6 is a top-surface view of a part of connection between power supply and ground in a package according to a first embodiment of the present invention.

A semiconductor chip 1 mounted on the semiconductor package according to the present embodiment has a pad row 29-1 close to the outer periphery of the semiconductor chip and a pad row 29-2 positioned inside the chip.

The wires for the power supply and ground are connected to the pads belonging to the pad row 29-1. The wires for the signal, ground, and I/O power supply are connected to the pads belonging to the pad row 29-2.

In a ground pad 26, short comb-tooth-shaped ground pads 31 and long comb-tooth-shaped ground pads 32 are provided so as to protrude in wiring shape portions surrounding the chip. Each of the comb-tooth-shaped pads 31 and 32 has a width by which two wires parallely extended from the pads belonging to the pad row 29-1 can be connected thereto. And, ground wires 12-1 and 12-2 having two different types of lengths from each other are bonded from the pads belonging to the pad row 29-1. Note that, since the preferred aim of the present invention is to expand the distance between the power supply and the ground wires larger than that between the pads on the chip side, difference in the length of the ground wires 12-1 and 12-2 is equal to or larger than the distance between the adjacent pads belonging to the pad row 29-1.

Ground wires 12-3 and 12-4 having two different types of lengths from each other are bonded from the pads belonging to the pad row 29-2 to the long comb-tooth-shaped ground pad 32. The difference in the length between the ground wires 12-3 and 12-4 is also equal to or larger than the distance between the adjacent pads belonging to the pad row 29-2.

Between the ground wires 12-1 and 12-2 (“between” used here means “between wires” and is not necessarily “between wire connecting points”) and between the ground wires 12-3 and 12-4, a space in which a via hole can be connected is provided to carry out the bonding. In each provided space, via holes 21-1 and 21-2 are provided.

In FIG. 6, in order to efficiently provide the pad widths necessary for the bonding, each of the short comb-tooth-shaped ground pad 31 and the long comb-tooth-shaped ground pad 32 has a parallelogram shape oblique to a tip of the chip. However, the present invention is not limited this.

A power-supply pad 25 is arranged at a position sandwiched by the short comb-tooth-shaped ground pad 31 and the long comb-tooth-shaped ground pad 32. A power-supply via is disposed in the vicinity of the ground via 21-2. In this manner, the connection between the power-supply pad 25 and a wiring in a lower layer not illustrated is established.

Similarly to each of the comb-tooth-shaped ground pads 31 and 32, the power-supply pad 25 also has a width by which two wires from the pads belonging to the pad row 29-1 can be bonded. The power-supply wires 11-1 and 11-2 connected to the power-supply pad 25 are connected to the pads belonging to the pad row 29-1 so as to be parallel to the ground wires connected to the comb-tooth-shaped ground pads 31 and 32. A wire length of the power-supply wire 11-1 is almost equal to that of the ground wire 12-1. Also, a wire length of the power-supply wire 11-2 is almost equal to that of the ground wire 12-2.

Between the power-supply wire 11-1 and the ground wire 12-1, the power-supply wire 11-2 or the ground wire 12-2 is arranged. At this time, each of the power-supply wire and the ground wire having substantially the same length is arranged in alternate chip pad. By such arrangement, the bonding interval to a package surface layer 30 can be about twice the distance between the pads belonging to the pad row 29-1. In this manner, even in a case of wire bonding with a narrow pitch, the power-supply wire and the ground wire having the same length can be parallelly arranged. As a result, the parasitic inductance can be decreased.

Also, in order to bond signal wires 13-1 and 13-2 to be parallel and close to the ground wires 12-3 and 12-4, signal pads 27-1 and 27-2 are arranged in the vicinity of a tip of the long comb-tooth-shaped ground pad 32.

The signal wire 13-1 is connected to the signal pad 27-1. The signal wire 13-1 is connected to the pad belonging to the pad row 29-2. A wire length of the signal wire 13-1 and a wire length of the ground wire 12-3 are almost equal to each other. Between the ground wire 12-3 and the signal wire 13-1, the ground wire 12-4 or the signal wire 13-2 is arranged. By such arrangement, similarly to the power-supply wire and the ground wire, the bonding interval to the package surface layer 30 can be twice the distance between the pads belonging to the pad row 29-2. In addition, even in a case of bonding with a narrow pitch, the signal wire and the ground wire can have the same length, and be parallel and close to each other. As a result, the parasitic inductance can be decreased.

Similarly, an I/O power-supply pad 28 is arranged in the vicinity of the signal pads 27-1 and 27-2. By such arrangement, power-supply wires 14-1 and 14-2 can be bonded so as to be close and parallel to the signal wires. As a result, the parasitic inductance can be decreased.

Note that, in order to be parallel to both the power-supply pad 25 and the I/O power-supply pad 28, the long comb-tooth-shaped ground pad 32 has a length twice or more a section which is parallel to the power-supply pad 25 and the power-supply pad 28.

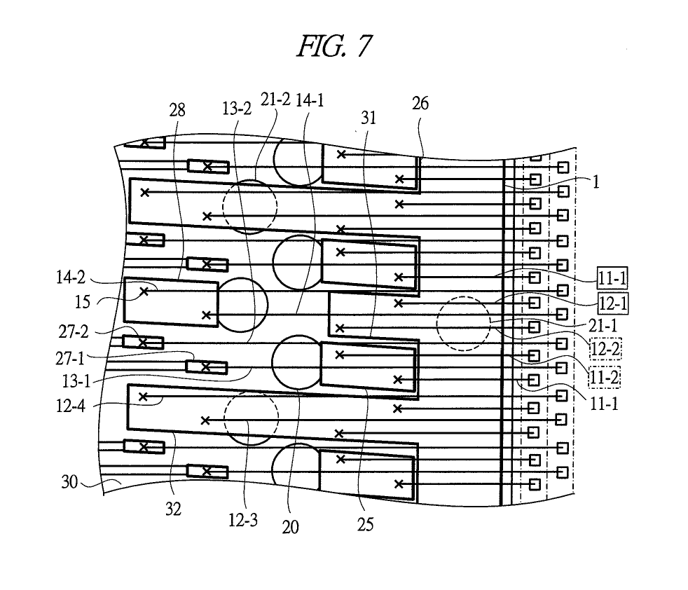

FIG. 7 is a top-surface view of a part of connection between the power supply and ground in another package according to the first embodiment of the present invention.

Also in the present drawing, the short comb-tooth-shaped ground pad 31 and the long comb-tooth-shaped ground pad 32 are provided on the package 2 so as to protrude from the ground pad 26. And, the point that the power-supply pad 25 is provided so as to be sandwiched by the short comb-tooth-shaped ground pad 31 and the long comb-tooth-shaped ground pad 32 is the same as that in FIG. 6.

However, as different from FIG. 6, the power-supply wire 11-1 and the ground wire 12-1 are arranged so as to be closest to each other. In the drawing, the reference numbers of the target power-supply wire 11-1 and ground wire 12-1 are surrounded by solid lines. Similarly, the power-supply wire 11-2 and the ground wire 12-2 having the same length are arranged so as to be closest to each other. In the drawing, the reference numbers of the target power-supply wire 11-2 and ground wire 12-2 are surrounded by chain lines.

By such arrangement, the mutual inductance between the power-supply wire and the ground wire can be maximized, so that the parasitic inductance between the wires can be decreased.

The embodiment of FIG. 7 puts a priority on the decrease in the parasitic inductance between the wires. The effect of expanding the bonding pitch on the package surface layer 30 is smaller than that in FIG. 6. However, the pad size is larger than that of the structure as described in Patent Document 1, which has the pad width for one wire, and therefore, the embodiment is easily applied to the bonding with a narrow pitch.

As described above, by decreasing the self inductance and increasing the mutual inductance as much as possible, the parasitic inductance can be decreased.

### Second Embodiment

Next, a second embodiment of the present invention will be explained.

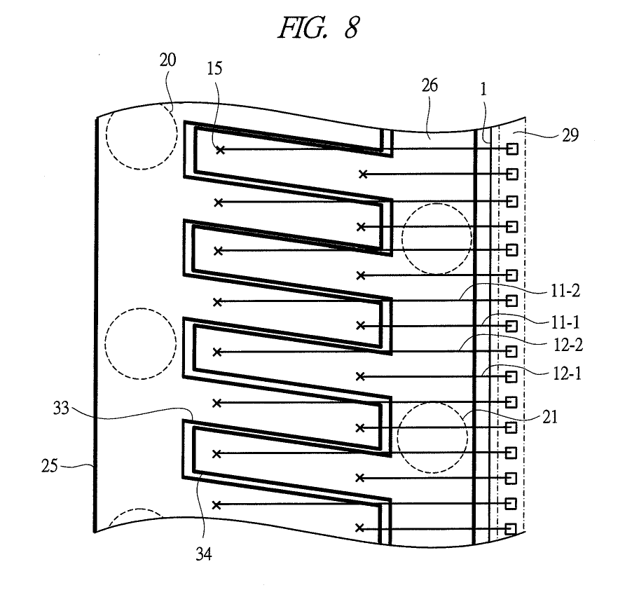

FIG. 8 is a top-surface view of a part of connection between power supply and ground in a package according to the second embodiment of the present invention. Note that FIG. 8 does not illustrate the signal wire and the I/O power-supply wire.

In the present embodiment, the decrease in the parasitic inductance between the power-supply wire and the ground wire is specialized.

In the present embodiment, the point that the comb-tooth-shaped ground pad 34 is protruded from the ground pad 26 is the same as the first embodiment. The present embodiment has a feature of a point that a comb-tooth-shaped power-supply pad 33 is protruded from the pad 25 on the wiring also for the power supply.

In the comb-tooth-shaped power-supply pad 33 and a comb-tooth-shaped ground pad 34, a short wire and a long wire are alternately arranged. Moreover, a pitch between the bonding wires on the package surface layer 30 is increased twice a distance between the adjacent pads arranged in a pad row 29.

Further, a difference in a length between the short wire and the long wire is equal to or larger than the distance between the adjacent pads arranged in the pad row 29.

In addition, power-supply via holes 20 and ground via holes 21 are connected to the power supply pad 25 and the ground pad 26, respectively.

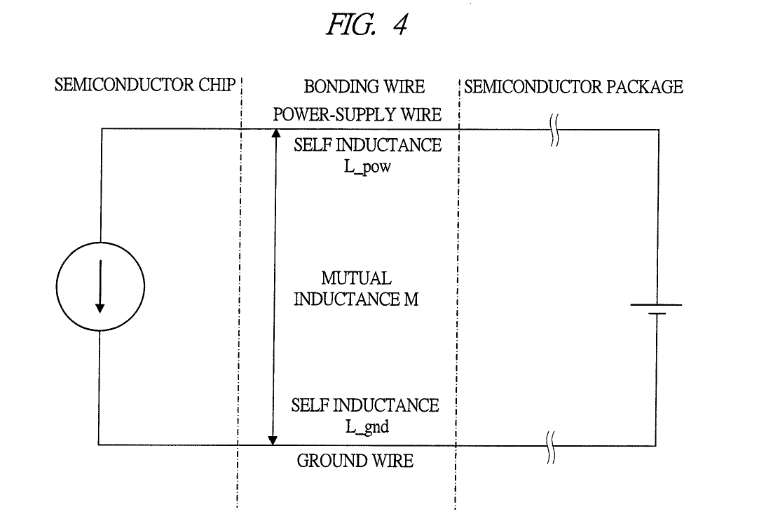

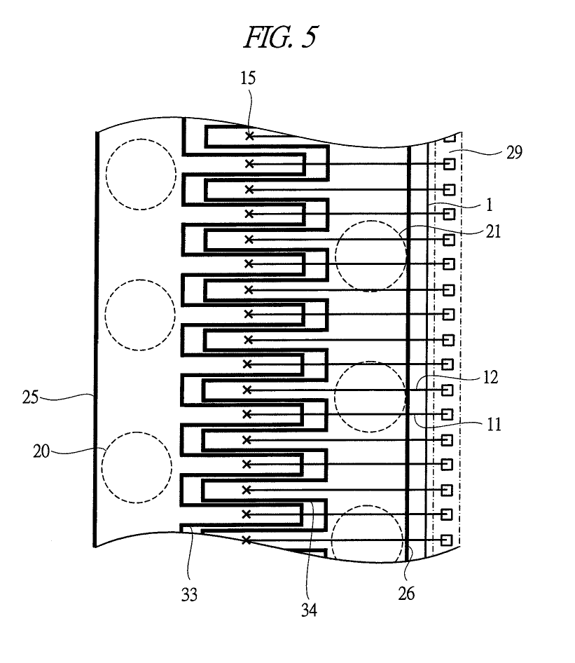

By such arrangement, the same effects as those of FIG. 7 can be exerted. Also, the arrangement can be easily replaced with the structure of FIG. 3 illustrated as a conventional embodiment, and is useful for decreasing the power-feed system inductance of various types of packages.

### Third Embodiment

Next, a third embodiment of the present invention will be explained.

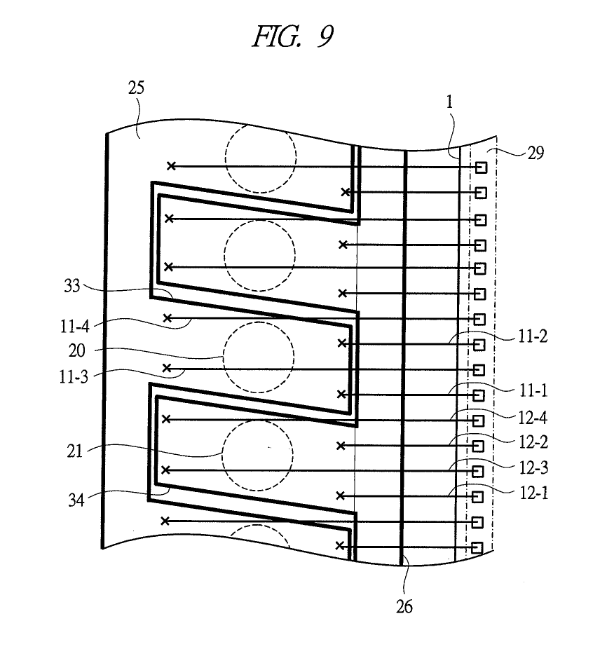

FIG. 9 is a top-surface view of a part of connection between power supply and ground in a package according to the third embodiment of the present invention.

In the third embodiment of the present invention, the decrease in the parasitic inductance between the power-supply wire and the ground wire is specialized similarly to the second embodiment.

The point that the power-supply pad 25 and the ground pad 26 have the comb-tooth-shaped pad portion is the same as the second embodiment. However, a point that each width of the comb-tooth-shaped power-supply pad 33 and the comb-tooth-shaped ground pad 34 is provided for four wires is different from the second embodiment.

The power-supply wires 11-1, 11-2, 11-3, and 11-4 having two types of lengths are bonded to the comb-tooth-shaped power-supply pad 33.

Also, the ground wires 12-1, 12-2, 12-3, and 12-4 having two types of lengths are bonded to the comb-tooth-shaped ground pad 34.

In these power-supply wires and the ground wires, a long wire and a short wire are alternately arranged. By such arrangement, similarly to the second embodiment, the bonding pitch on the package surface layer can be expanded, and the power-supply wire and the ground wire having the same length can be arranged to be close and parallel to each other even in a case of bonding with a narrow pitch. As a result, the parasitic inductance caused by the wires can be decreased.

Further, in the present embodiment, by providing each width of the comb-tooth-shaped power-supply pad 33 and the comb-tooth-shaped ground pad 34 for four wires, the power-supply via hole 20 and the ground via hole 21 can be arranged on the comb-tooth-shaped power-supply pad 33 and the comb-tooth-shaped ground pad 34, respectively. By such arrangement, the present embodiment is advantageous in the point that the parasitic inductance of the via holes can also be decreased since the power-supply via hole 20 and the ground via hole 21 are arranged to be close to each other.

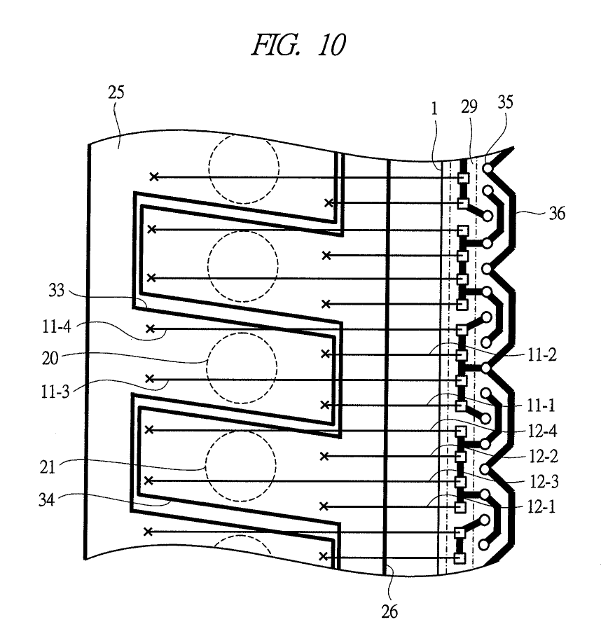

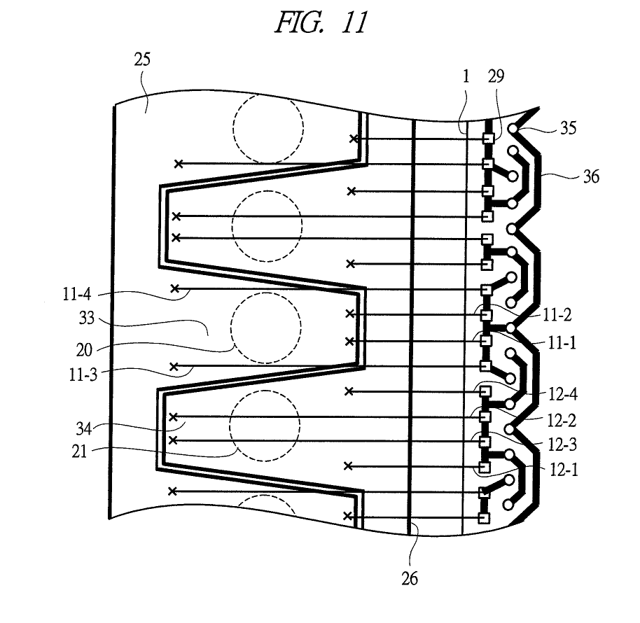

FIG. 10 is a top-surface view of a part of connection between power supply and ground in a chip according to the third embodiment of the present invention.

The arrangement of wire bonding and the shapes of the power-supply pad 25 and the ground pad 26 in this drawing are the same as those of FIG. 9.

The present drawing newly discloses points that connecting points 35 with the inner-chip wiring, where power supply and ground are alternately arranged, are provided as different from the wire pad on the semiconductor chip 1 side and that an on-chip wiring 36 connects between the connecting points.

By such arrangement of the connecting points 35 by the inner-chip wiring so that the power supply and ground are alternately arranged, continuous four points for each of the power supply and ground are arranged in the wire pad on the chip side, so that unevenness of inner-chip power feed can be avoided.

FIG. 11 is a top-surface view of a part of connection between power supply and ground in another chip according to the third embodiment of the present invention.

In the present drawing, the point that the power-supply pad 25 and the ground pad 26 have the comb-tooth-shaped power-supply pad 33 and the comb-tooth-shaped ground pad 34 is also the same. However, different points are that the bonding is carried out so that a trapezoid is formed when the connecting points of the power-supply wire 11-4 and the ground wires 12-1 to 4 are connected to each other in the comb-tooth-shaped power-supply pad 33 and the comb-tooth-shaped ground pad 34 in the present drawing and that the comb-tooth-shaped pads 33 and 34 are also a trapezoid.

By forming the comb-tooth-shaped pads in the trapezoidal, there is an advantage that a space for arranging the power-supply via hole 20 and the ground via hole 21 in the comb-tooth-shaped pads 33 and 34 can be widely provided.

In the foregoing, the invention made by the present inventors has been concretely described based on the embodiments. However, it is needless to say that the present invention is not limited to the foregoing embodiments and various modifications and alterations can be made within the scope of the present invention.

The present invention relates to a wire bonding method for a semiconductor chip. The present invention can be widely applied without limitation to an application circuit, that is a CPU, a wireless communication circuit, or others, which is mounted on a semiconductor chip.

What is claimed is:

1. A semiconductor package mounting a semiconductor chip and having connection with the semiconductor chip by wire bonding, wherein
the semiconductor package has a ground pad, which is a connecting point for the wire bonding, on a surface layer of the semiconductor package,
the ground pad has a comb-tooth-shaped ground pad protruding on the surface layer of the semiconductor package, and
two or more ground wires are connected to the comb-tooth-shaped ground pad.

2. The semiconductor package according to claim 1, wherein
the semiconductor package further has a power-supply pad to which two or more power-supply wires are connected, and
one ground wire of the two or more ground wires and one power-supply wire of the two or more power-supply wires are substantially parallel to each other and have substantially the same length to be a pair.

3. The semiconductor package according to claim 2, wherein
two or more comb-tooth-shaped ground pads are provided, and
the power-supply pad is arranged on the surface layer of the semiconductor package so as to be sandwiched by two comb-tooth-shaped ground pads.

4. The semiconductor package according to claim 1, wherein
a difference between lengths of the two or more ground wires connected to the comb-tooth-shaped ground pad is equal to or larger than a distance between wire pads on the semiconductor chip side.

5. The semiconductor package according to claim 4, wherein
a part of the comb-tooth-shaped ground pad has a length which is twice a portion parallel to the power-supply pad or larger,
a ground wire having a length different from that of the ground wire is connected from the semiconductor chip to a tip side of the comb-tooth-shaped ground pad having the length which is twice or larger, and
a signal wire is arranged so as to be parallel to the ground wire connected to the tip side of the comb-tooth-shaped ground pad having the length which is twice or larger.

6. The semiconductor package according to claim 5, wherein
the semiconductor package further has an I/O power-supply pad on the surface layer of the semiconductor package, and
an I/O power-supply wire is connected to the I/O power-supply pad so as to be parallel to the signal wire.

7. The semiconductor package according to claim 6, wherein
the semiconductor package has:
a power-supply via hole so as to be in contact with an outer peripheral side of the semiconductor package of the power-supply pad;
an I/O power-supply via hole so as to be in contact with the semiconductor chip side of the I/O power-supply pad; and
a ground via hole in the comb-tooth-shaped ground pad in the vicinity of the power-supply via hole or the I/O power-supply via hole.

8. The semiconductor package according to claim 7, wherein
a long wire and a short wire are alternately arranged to each other as the I/O power-supply wire and the ground wire being parallel to the I/O power-supply wire and having the same length as that of the I/O power-supply wire, and
a long wire and a short wire are alternately arranged to each other as the signal wire and the ground wire being parallel to the signal wire and the I/O power-supply wire and having the same length as those of the signal wire and the I/O power-supply wire.

9. A semiconductor package mounting a semiconductor chip and having connection with the semiconductor chip by wire bonding, wherein
the semiconductor package has a ground pad and a power-supply pad, which are connecting points for the wire bonding, on a surface layer of the semiconductor package,
the ground pad has a comb-tooth-shaped ground pad protruding on the surface layer of the semiconductor package,
the power-supply pad has a comb-tooth-shaped power-supply pad protruding on the surface layer of the semiconductor package, and
the comb-tooth-shaped ground pad and the comb-tooth-shaped power-supply pad are adjacent to each other in a peripheral direction of the semiconductor package.

10. The semiconductor package according to claim 9, wherein
the ground pad is arranged in an inner peripheral side of the semiconductor package, and the power-supply pad is arranged in an outer peripheral side of the semiconductor package.

11. The semiconductor package according to claim 10, wherein
two wires having different lengths from each other are arranged in each of the comb-tooth-shaped ground pad and the comb-tooth-shaped power-supply pad, and
a long wire and a short wire are alternately arranged to each other as each of the two wires arranged in the comb-tooth-shaped ground pad and the two wires arranged in the comb-tooth-shaped power-supply pad.

12. The semiconductor package according to claim 11, wherein
the comb-tooth-shaped ground pad and the comb-tooth-shaped power-supply pad are shaped in a substantially parallelogram oblique to a tip of the chip.

13. The semiconductor package according to claim 10, wherein
total four wires having two types of lengths are arranged in the comb-tooth-shaped ground pad, and
a via hole for ground connection is arranged between connecting points for the long wire and the short wire arranged in the comb-tooth-shaped ground pad.

14. The semiconductor package according to claim 13, wherein
the comb-tooth-shaped ground pad is shaped in a parallelogram oblique to a tip of the chip, and each connecting position for the four wires connected to the same comb-tooth-shaped ground pad is arranged so as to have the same distance from a center line of the comb-tooth-shaped ground pad.

15. The semiconductor package according to claim 13, wherein
the comb-tooth-shaped ground pad is shaped in a trapezoid oblique to the tip of the chip, and each connecting position for the four wires connected to the same comb-tooth-shaped ground pad is arranged so as to have the same distance from a center line of the comb-tooth-shaped ground pad.

16. The semiconductor package according to claim 10, wherein
total four wires having two types of lengths are arranged in the comb-tooth-shaped power-supply pad, and
a via hole for power-supply connection is arranged between connecting points for the long wire and the short wire arranged in the comb-tooth-shaped power-supply pad.

17. The semiconductor package according to claim 16, wherein
the comb-tooth-shaped power-supply pad is shaped in a parallelogram oblique to a tip of the chip, and each connecting position for the four wires connected to the same comb-tooth-shaped power-supply pad is arranged so as to have the same distance from a center line of the comb-tooth-shaped power-supply pad.

18. The semiconductor package according to claim 16, wherein
the comb-tooth-shaped power-supply pad is shaped in a trapezoid oblique to a tip of the chip, and each connecting position for the four wires connected to the same comb-tooth-shaped power-supply pad is arranged so as to have the same distance from a center line of the comb-tooth-shaped power-supply pad.

19. The semiconductor package according to claim 18, wherein
the semiconductor package has a wiring connected to a wire pad on the surface layer of the semiconductor chip, and
power supply and ground are alternately arranged to each other at a connecting portion with wiring in the semiconductor chip.
